(19) United States
(12) Patent Application Publication
(10) Pub. No.: US 2005/0148196 A1
(43) Pub. Date: Jul. 7, 2005

(54) Method and system for patterning material in a thin film device

(76) Inventors: Manish Sharma, Mountain View, CA (US); Thomas C. Anthony, Sunnyvale, CA (US); Hoon Lee, Pohang-Si (KR)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/746,170

(22) Filed: Dec. 26, 2003

(51) Int. Cl. H01L 21/302; H01L 21/461

(52) U.S. Cl. 438/745

(57) ABSTRACT

An aspect of the present invention is a method of patterning material in a thin-film device. The method includes forming a liftoff stencil, depositing a first layer of material through the liftoff stencil, depositing a second layer of material through the liftoff stencil, removing at least a portion of the liftoff stencil and performing a directional etch on the first and second layer of material.

### FIELD OF THE INVENTION

The present invention relates generally to thin-film devices and more particularly to a method and system for patterning material in a thin-film device.

### BACKGROUND OF THE INVENTION

Rapid growth of information communicating apparatuses, such as a PDA (Personal Digital Assistant), demands higher integration, faster speed, and lower power consumption for memory elements and logic elements available for constituting these communicating apparatuses. In particular, realization of higher density and greater capacity of non-volatile memories has become a more important issue for the art of replacing such a hard disk or an optical disk which is difficult to be down-sized due to presence of moving elements.

Current non-volatile memories include flash memory, which is based on semiconductor technology and FRAM (Ferro-electric Random Access Memory), which is based on a ferro-dielectric technology. Nevertheless, flash memory is problematic in the sense that the writing speed remains on the order of micro-seconds and the re-write cycles are limited. FRAM is problematic in the sense that it is difficult to scale to ultra-high density and the re-writable cycles are insufficient.

A magnetic random access memory (MRAM), on the other hand, is a non-volatile memory that is free from the above-described problems. Due to improvement in physical characteristics of TMR (Tunnel Magneto-Resistive) materials in recent years, MRAM has drawn much attention in this field.

Because of its simple constitution, MRAM can readily be formed into highly integrated configurations. Inasmuch as MRAM executes a write operation by rotation of a magnetic moment, it is possible to secure sufficient re-writable cycles. Further, it is expected that the MRAM can execute accessing operations at an extremely high-speed (e.g. on the order of nano-seconds).

Conventional MRAM manufacturing methods typically do not utilize a lift-off technique. However, this technique is used in manufacture of abutted-junction magnetoresistive recording heads for hard disk drives. Using photo-resist for a mask material in forming elements, this method uses a single masking step to pattern one material by an etching process and a second material by a subsequent deposition and lift-off process. The resulting structure has a region of contact between the etched and lifted films defined by the boundary of the photoresist mask.

This implementation creates a contact region between two films in the same plane. However, for many device applications it is desired to produce a contact region between films on different planes. In particular, it is desirable that the contact does not introduce an electrical short circuit across the device being contacted.

Accordingly, what is needed is a method and system for patterning material in a thin-film device that creates sharper patterned features and minimizes any potential shorting of the device. The method and system should be simple, inexpensive and capable of being easily adapted to existing technology. The present invention addresses this need.

### SUMMARY OF THE INVENTION

An aspect of the present invention is a method of patterning material in a thin-film device. The method includes forming a liftoff stencil, depositing a first layer of material through the liftoff stencil, depositing a second layer of material through the liftoff stencil, removing at least a portion of the liftoff stencil and performing a directional etch on the first and second layers of material.

Other aspects and advantages of the present invention will become apparent from the following detailed description, taken in conjunction with the accompanying drawings, illustrating by way of example the principles of the invention.

### BRIEF DESCRIPTION OF THE DRAWINGS

The drawings referenced herein form a part of the specification. Features shown in the drawing are meant as illustrative of only some embodiments of the invention, and not of all embodiments of the invention, unless otherwise explicitly indicated, and implications to the contrary are otherwise not to be made.

FIG. 1 is a high-level flow chart of a method in accordance with an embodiment of the present invention.

FIG. 2A shows a structure whereby two different layers are employed to create a liftoff stencil in accordance with an embodiment of the present invention.

FIG. 2B shows the structure after the deposition of the TMR junction material in accordance with an embodiment of the present invention.

FIG. 2C shows the structure after the deposition of the hardmask layer in accordance with an embodiment of the present invention.

FIG. 2D shows the structure after the first and second photo-resists have been removed in accordance with an embodiment of the present invention.

FIG. 2E shows the structure after the performance of the directional etch in accordance with an embodiment of the present invention.

### DETAILED DESCRIPTION

The present invention relates to a method and system for patterning material in a thin-film device. The following description is presented to enable one of ordinary skill in the art to make and use the invention and is provided in the context of a patent application and its requirements. Various modifications to the embodiments and the generic principles and features described herein will be readily apparent to those skilled in the art. Thus, the present invention is not intended to be limited to the embodiment shown but is to be accorded the widest scope consistent with the principles and features described herein.

As shown in the drawings for purposes of illustration, the present invention is a method and system for patterning material in a thin-film device. The method and system allow less directional deposition processes to be utilized in conjunction with a liftoff stencil to achieve sharply defined patterned features. By allowing less directional deposition processes to be utilized to achieve sharply defined patterned features, different deposition and etching processes can be combined thereby increasing the flexibility of the manufacturing process. Additionally, by implementing a directional etch in conjunction with a liftoff stencil, the potential occurrence of shorts in the resulting thin-film device is minimized.

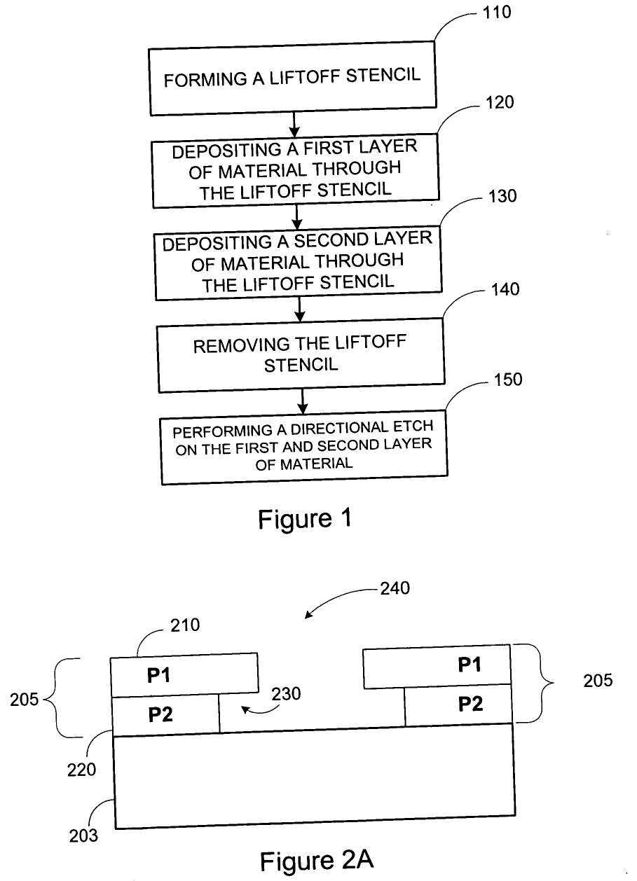

FIG. 1 is a high level flow chart of a method for patterning material in a thin-film device. A first step 110 includes forming a liftoff stencil. A second step 120 includes depositing a first layer of material through the liftoff stencil. A third step 130 includes depositing a second layer of material through the liftoff stencil. A fourth step 140 involves removing the liftoff stencil. A final step 150 includes performing a directional etch on the first and second layer of material.

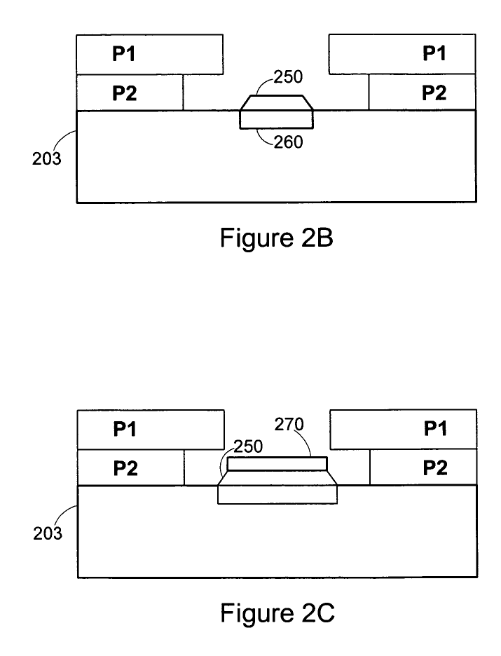

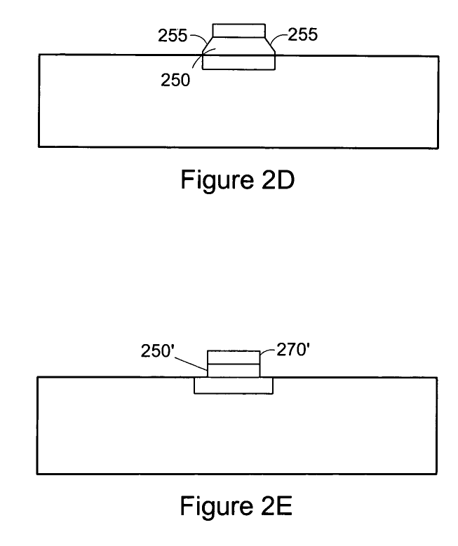

In an embodiment, step 110 is accomplished with two different layers of material. FIG. 2A shows a structure whereby two different layers of material are employed to create a liftoff stencil. As can be seen in FIG. 2A, the liftoff stencil 205 is on a substrate 203 and includes a first layer of material 210 and a second layer of material 220. The distance that the first layer of material 210 extends past the second layer of material 220 is defined as an undercut 230. The geometries of the first layer of material 210 determine the size of opening 240.

The first and second layers of material 210, 220 can be a variety of different materials. For example, in an embodiment, the first and second layers of material 210, 220 are photo-resist materials whereby each layer of photo-resist material is capable of being etched in a selective fashion. Additionally, one or both the first and second layers of material 210, 220 can be a dielectric material such as a spin-on glass (SOG) material, SiO₂, Si₃N₄, Al₂O₃ or any of a variety of dielectric materials.

Furthermore, although the liftoff stencil is described as being formed with two layers of material, one of ordinary skill will readily recognize that the liftoff stencil could be formed with a number of different layers while remaining within the spirit and scope of the present invention. For example, in an alternate embodiment, a trilayer stencil structure is implemented wherein the trilayer structure includes an inorganic transfer layer. This allows subsequent deposition processes to be performed at a higher temperature thereby increasing the flexibility of the manufacturing process.

In an embodiment, step 120 is accomplished by utilizing deposition techniques to deposit at least one material through the opening 240. In an MRAM device, this step involves the deposition of requisite materials for forming a magnetic memory element. A magnetic memory element has a resistance that is dependent upon the magnetic state thereof. Examples of such elements include magnetic tunnel junctions (the TMR junction is a type of magnetic tunnel junction) and giant magnetoresistance (“GMR”) spin valves.

Although the embodiment is described in conjunction with the formation of an MRAM device, one of ordinary skill in the art will readily recognize that the described processes could be implemented in conjunction with the formation of a variety of different types of devices while remaining within the spirit and scope of the present invention.

Step 120 is accordingly accomplished by depositing through the opening 240 the requisite materials to form a TMR junction 250. In an embodiment, the TMR junction 250 is made up of an insulator layer sandwiched between two ferromagnetic layers and is deposited onto an existing bottom conductor 260. FIG. 2B shows TMR junction 250 and the bottom conductor 260.

The TMR junction 250 materials are deposited utilizing one of a variety of different deposition techniques. These techniques include, but are not limited to, sputtering, chemical vapor deposition, plasma deposition, evaporation, atomic layer deposition or laser ablation.

Sputtering utilizes a low-pressure plasma to generate large numbers of positive ions to bombard and dislodge atoms from the target material. The plasma is generated in an inert gas. The potential that is created between the substrate and the source target accelerates the ion towards the target. When the bombardment energy exceeds roughly four times the bond energy of a solid, atoms from the source are knocked loose and deposited on the substrate to form a thin film.

Chemical vapor deposition (CVD) involves chemical reactions which transform gaseous molecules, called a precursor, into a solid material, in the form of thin film or powder, on the surface of a substrate. With CVD, it is possible to produce almost any metallic or non-metallic element, including carbon and silicon, as well as compounds such as carbides, nitrides, borides, oxides, intermetallics and many others.

Plasma deposition is a powerful tool for many film deposition processes that cannot be achieved with temperature control alone. Plasmas can be broadly divided into “thermal” and “cold” varieties. A thermal plasma is a high temperature plasma i.e. the average energy of particles, kT, is high enough to separate electrons from their atoms on a regular basis (typically greater than 5000 K). A cold plasma is a plasma in which only the electrons are hot, with neutrals and ions being at modest temperature e.g. well below ionization energies. This is possible because electrons, being much lighter than atoms, exchange energy very poorly with atoms.

Consequently, thousands of collisions are required for an electron to exchange energy with a population of heavy atoms or molecules. If the ratio of the system size to the mean free path is small enough, the electrons don't have enough time to exchange energy with ions before running into a wall or being pumped away. Accordingly, energy is coupled into the electrons without heating the gas. This discrepancy between electron and gas temperatures makes cold plasmas of great interest for planar processing, and in particular for chemical vapor deposition.

Atomic layer deposition (ALD) is a process in which a thin film is deposited by means of alternating saturated surface reactions. These reactions are implemented by directing gaseous or vaporized source materials alternately into a reactor and by rinsing the reactor with an inert gas between the source material pulses. Since the film grows through saturated surface reactions, the growth is self-controlled, in which case controlling the film thickness by the number of reaction cycles is precise and simple.

Films deposited by the ALD process are of uniform thickness over even large surface areas. Additionally, the conformality of the films is excellent. Process technology and equipment are commercially supplied under the trademark ALCVD™ by ASM Microchemistry Oy, Espoo, Finland.

The metal source materials used in the oxide processes in ALD are metal compounds of many types, in particular halides, alkoxides, .beta.-diketonates, alkyls, or cyclopentadienyls. The most commonly used oxygen source materials are water, hydrogen peroxide and ozone. Alcohols, oxygen and nitrous oxide have also been used. Of these, oxygen reacts very poorly at the temperatures below 600° C., but the other oxygen sources are highly reactive with most of the metal compounds listed above.

Laser ablation deposition can also be employed to deposit the TMR junction 260 in a less directional fashion. A typical laser utilized to employ laser ablation deposition is a Lambda Physik model 1248 pulsed excimer gas laser with an operating UV wavelength of 248 nanometers. Many other suitable lasers may be substituted (e.g. a Nd:YAG laser operating at 255-1064) while remaining within the spirit and scope of the present invention. The laser beam will produce a particle flux generally perpendicular to the surface of the target.

The laser wavelength is selected based on the nature of the material to be ablated. A high absorption coefficient and low reflectivity is a factor to consider for efficient removal of the material by the ablation process. The absorption coefficient is dependent on the type of material and the laser wavelength, and in some cases the intensity of the laser beam. Typically, as the surface temperature is increased, the absorption coefficient of the material increases. Thus the selection of laser wavelength is dependent on the type and characteristics of materials ablated.

Additionally, for wavelengths in the blue and ultraviolet region of the spectrum, the absorption coefficient increases and the reflectivity decreases. Thus, although any wavelength could be used, the use of wavelengths less than 350 nm may lead to more efficient removal of the material.

Since the laser system and the laser ablation chamber are preferably separate, the process offers great latitude for varying experimental parameters. With the proper laser choice this process can be used to create coatings of many different materials on particulates. The composition of the coatings is dependent on the laser processing parameters, such as incident energy fluence (J/cm.sup.2), laser repetition frequency, target to substrate distance, and optical absorption coefficient of the target.

However, if a compact laser is employed e.g. a solid-state laser operating from 248 to 1056 nm, the laser can be attached to the side of the chamber. The specific conditions which affect the deposition of coatings include (i) control of the laser influence; (ii) control of the laser spot size; (iii) control of the gas composition and flow rate; (iv) control over the pulsation rate; and (v) number of pulses and wavelength of the light. By controlling each of these parameters, which are different for different materials, the integrity, microstructure, topology, architecture, thickness and adhesion of the coatings on the drug particles can be varied. Although several deposition techniques have been disclosed, one of ordinary skill in the art will readily recognize that a variety of different deposition techniques could be implemented.

Referring back to FIG. 1, after depositing the requisite materials for the TMR junction 250, step 130 involves the deposition of a hardmask layer 270 in contact with the TMR junction 250. The hardmask layer 270 could be a metal layer such as tantalum, titanium, tungsten, or other layers such as silicon nitride/oxide or TaN. The hardmask layer 270 is deposited through the opening 240 in a more directional fashion than the underlying material, i.e. TMR junction 250, since the hardmask layer 270 serves as a defining mask. For example, if the TMR junction 250 material is deposited via a sputtering process, the hardmask layer 270 is deposited via a more directional process such as e-beam or thermal evaporation.

In an e-beam or thermal evaporation process, the source material is heated in vacuum by an electron beam, laser beam or a resistive heater to the point that the source material evaporates or sublimes. Since the process is conducted in vacuum, the evaporated atoms or molecules (the evaporant) proceed to the substrate in a line-of-sight fashion. Such a highly directional deposition process produces an accurate transfer of the liftoff stencil dimensions to the deposited film. FIG. 2C shows the structure after the deposition of the hardmask layer 270.

Step 140 is accomplished by removing the first layer of material 210 and the second layer of material 220 utilizing conventional etching methodology. FIG. 2D shows the structure after the first and second layers of material 210, 220 have been removed. As can be seen, the TMR junction 250 includes sloped portions 255.

The embodiment described in FIGS. 2A-2E indicates removal of both layers of material 210 and 220 in step 140. In other implementations it may be desirable to leave material 220 behind, and only remove material 210 in step 140. Consequently, step 140 is accomplished by removing at least a portion of the liftoff stencil defined by layers of material 210 and 220.

The final step 150 involves performing a directional etch on the TMR junction 250 and the hardmask layer 270. By performing a directional etch on the TMR junction 250 and the hardmask layer 270, the sloped portions 255 (see FIG. 2D) of the TMR junction 250 are removed, thereby minimizing any potential shorts in the resultant device. Here the hardmask layer 270 serves as a defining mask.

The directional etch is performed utilizing one of a variety of different directional etching techniques. These techniques include, but are not limited to, ion-milling, and anisotropic reactive ion etching (RIE).

Ion-milling is a physical dry etching technique where a sample is exposed to a collimated beam of accelerated, mono-energetic inert ions thereby removing material due to ion impingement. The ion-milling systems typically incorporate a double-gridded ion source of the Kaufman type that supply acceleration voltages ranging from ˜200 V to ˜1.5 kV. Argon (p˜2 E-4 Torr) is typically used as the working gas. The sample is mounted on a rotating water-cooled stage that can be tilted with respect to the incoming Ar-ions.

Ion-milling is used for the fabrication of sub-micron gratings as well as for structuring samples incorporating very different materials such as metal/insulator/semiconductor-combinations since the etch rates of these materials are of comparable magnitude (e.g. GaAs: 80 nm/min, Au: 75 nm/min, silicon nitride: 25 nm/min, photoresist: ˜20 nm/min for 500 eV-Ar ions). Accordingly, ion-milling provides a very flexible tool for the performance of directional etching.

In anisotropic RIE, the substrate is placed inside a reactor in which several gases are introduced. A plasma is struck in the gas mixture using an RF power source, breaking the gas molecules into ions. The ions are accelerated towards, and reacts at, the surface of the material being etched, forming another gaseous material. This is known as the chemical part of reactive ion etching. There is also a physical part which is similar in nature to the sputtering deposition process.

If the ions have high enough energy, they can knock atoms out of the material to be etched without a chemical reaction. It is a very complex task to develop dry etch processes that balance chemical and physical etching, since there are many parameters to adjust. By changing the balance it is possible to influence the anisotropy of the etching, since the chemical part is isotropic and the physical part is highly anisotropic. Accordingly, RIE is capable of performing a very directional etch.

FIG. 2E shows the structure after the performance of the directional etch. As can be seen in FIG. 2E, the sloped portions 255 of FIG. 2D have been removed via the directional etch process. Remaining on the structure are the etched TMR junction 250′ and the etched hardmask layer 270′.

Although an ion-milling process and an anisotropic RIE process have been disclosed as possible ways to implement a directional etch, one of ordinary skill in the art will readily recognize that a variety of directional etching processes could be implemented while remaining within the spirit and scope of the present invention.

A method and system for patterning material in a thin-film device is disclosed. The method and system allow less directional deposition processes to be utilized in conjunction with a liftoff stencil to achieve sharply defined patterned features. By allowing less directional deposition processes to be utilized to achieve sharply defined patterned features, different deposition and etching processes can be combined thereby increasing the flexibility of the manufacturing process. Additionally, by implementing a directional etch in conjunction with a liftoff stencil, the potential occurrence of shorts in the resulting thin-film device is minimized.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

1. A method of patterning material in a thin-film device comprising:
forming a liftoff stencil;
depositing a first layer of material through the liftoff stencil;
depositing a second layer of material through the liftoff stencil;
removing at least a portion of the liftoff stencil; and
performing a directional etch on the first and second layer of material.

2. The method of claim 1 wherein the thin-film device comprises a magnetic random access memory device.

3. The method of claim 1 wherein depositing a first layer of material through the liftoff stencil further comprises:
depositing the first layer of material via a first process.

4. The method of claim 1 wherein forming the liftoff stencil further comprises:
forming the liftoff stencil with a plurality of photo-resists wherein the plurality of photo-resists further comprises a first layer and a second layer of photo-resist.

5. The method of claim 1 wherein performing a directional etch further comprises:
utilizing an ion milling process to perform the directional etch.

6. The method of claim 1 wherein performing a directional etch further comprises:
utilizing an anisotropic REE process to perform the directional etch.

7. The method of claim 1 wherein the first layer comprises a TMR junction and the second layer comprises a hardmask layer.

8. The method of claim 3 wherein depositing a second layer of material through the liftoff stencil further comprises:
depositing the second layer of material via a second process.

9. The method of claim 4 wherein the first and second layer of photo-resist form an undercut.

10. The method of claim 8 wherein the second layer of material comprises a hardmask layer.

11. The method of claim 10 wherein the hardmask layer comprises at least one of tantalum, titanium, tungsten, silicon nitride, silicon oxide and tantalum nitride.

12. The method of claim 9 wherein the second process is more directional than the first process.

13. A system of patterning material in a thin-film device comprising:
means for forming a liftoff stencil;
means for depositing a first layer of material through the liftoff stencil;
means for depositing a second layer of material through the liftoff stencil and in contact with the first layer;
means for removing at least a portion of the liftoff stencil; and
means for performing a directional etch on the first and second layer of material.

14. The system of claim 13 wherein the thin-film device comprises a magnetic random access memory device.

15. The system of claim 13 wherein the means for depositing a first layer of material through the liftoff stencil further comprises:
means for depositing the first layer of material via a first process.

16. The system of claim 13 wherein the means for forming the liftoff stencil includes means for utilizing a plurality of photo-resists to form the liftoff stencil wherein a plurality of photo-resists further comprises a first layer and a second layer of photo-resist.

17. The system of claim 13 wherein the means for performing a directional etch further comprises:
means for utilizing an ion milling process to perform the directional etch.

18. The system of claim 13 wherein the means for performing a directional etch further comprises:
means for utilizing an anisotropic RIE process to perform the directional etch.

19. The system of claim 15 wherein the means for depositing a second layer of material through the liftoff stencil further comprises:
means for depositing the second layer of material via a second process.

20. The system of claim 16 wherein the first and second layer of photo-resist form an undercut.

21. The system of claim 18 wherein the first layer comprises a TMR junction and the second layer comprises a hardmask layer comprising at least one of tantalum, titanium, tungsten, silicon nitride, silicon oxide and TaN.

22. The system of claim 19 wherein the second layer of material comprises a hardmask layer.

23. The system of claim 22 wherein the hardmask layer comprises at least one of tantalum, titanium, tungsten, silicon nitride, silicon oxide and tantalum nitride.

24. The system of claim 22 wherein the second process is more directional than the first process.

25. A method of patterning a magnetic random access memory device comprising:
forming a liftoff stencil with a first and second layer of material;
depositing TMR junction material through the liftoff stencil;
depositing a hardmask layer through the liftoff stencil and in contact with the TMR junction material;
removing at least a portion of the liftoff stencil; and
performing a directional etch on the hardmask layer and the TMR junction material.

26. The method of claim 25 wherein depositing the TMR junction material through the liftoff stencil further comprises:
depositing the TMR junction material via a first process.

27. The method of claim 26 wherein depositing a hardmask layer through the liftoff stencil and in contact with the TMR junction material further comprises:
depositing the hardmask layer through the liftoff stencil and in contact with the TMR junction material via a second process.

28. The method of claim 27 wherein the hardmask layer comprises at least one of tantalum, titanium, tungsten, silicon nitride, silicon oxide and tantalum nitride.

29. The method of claim 27 wherein the second process is more directional than the first process.
